(19) United States
(12) Patent Application Publication
(10) Pub. No.: US 2025/0212394 A1
(43) Pub. Date: Jun. 26, 2025

(54) MEMORY DEVICE HAVING CONTROLLABLE BACK GATES AND SHIELDING BIT LINES

(71) Applicant: Samsung Electronics Co., Ltd., Suwon-si (KR)

(72) Inventors: Changyoung Lee, Suwon-si (KR); Chulkwon Park, Suwon-si (KR); Sanghoon Jung, Suwon-si (KR); Kyuchang Kang, Suwon-si (KR)

(21) Appl. No.: 18/888,358

(22) Filed: Sep. 18, 2024

(30) Foreign Application Priority Data
Dec. 21, 2023 (KR) 10-2023-0188794

(51) Int. Cl. H10B 12/00; G11C 11/4094; H01L 23/00; H01L 25/065; H01L 25/18; H10B 80/00

(52) U.S. Cl. CPC H10B 12/482; G11C 11/4094; H01L 24/08; H01L 25/0657; H01L 25/18; H10B 12/315; H10B 80/00; H01L 2224/08145; H01L 2924/1431; H01L 2924/1436

(57) ABSTRACT

A memory device includes a plurality of memory blocks and a voltage generator. Each of the plurality of memory blocks may include a plurality of word lines extending in a first direction of the memory device, a plurality of back gate lines that are each adjacent to a respective word line of the plurality of word lines, a plurality of bit lines extending in a second direction perpendicular to the first direction, and a shielding bit line arranged between the plurality of bit lines and under the plurality of bit lines. The back gate lines are electrically connected to the shielding bit line. The voltage generator may be configured to drive the shielding bit line and the plurality of back gate lines of each of the plurality of memory blocks at the same voltage level.

### CROSS-REFERENCE TO RELATED APPLICATION

This application is based on and claims priority under 35 U.S.C. § 119 to Korean Patent Application No. 10-2023-0188794, filed on Dec. 21, 2023, in the Korean Intellectual Property Office, the disclosure of which is incorporated by reference herein in its entirety.

### BACKGROUND

Aspects of the inventive concept relate to a memory device, more particularly, to a memory device in which shielding bit lines and back gates of memory cells are controlled.

According to the recent tendency of multifunctionalization of information and communication devices, a larger capacity and a higher degree of integration of memory devices have been desirable. Due to the reduction in size of memory cells for higher degree of integration, operation circuits and/or wiring structures included in the memory devices for operations and electrical connection of the memory devices have become complex. There has been a demand for memory devices having excellent electrical characteristics and improved integration degree. To improve the storage capacity and integration degree of memory devices, vertical channel transistors formed vertically on a semiconductor substrate have been introduced instead of planar channel transistors which are formed on a semiconductor substrate in a planar fashion.

Memory devices, for example, dynamic random access memory (DRAM) may include a plurality of memory cells including a vertical channel transistor and a capacitor and may be operated through writing and reading of data by charges stored in the capacitor. The memory cells may be connected to word lines and bit lines. According to the miniaturization of vertical channel transistors, the threshold voltage of the vertical channel transistors may decrease, which leads to generation of leakage current. Moreover, the coupling noise between bit lines may increase. To control the threshold voltage of the vertical channel transistors, a back gate electrode may be formed in the vertical channel transistors, and to reduce the coupling noise between the bit lines, shielding bit lines may be formed in a memory cell array.

During the operation of DRAM, to enable a word line connected to a selected memory cell, for example, a high voltage may be applied thereto. When the word line voltage increases, the voltage of the back gate electrode coupled to the word line may change. According to a change in the voltage level of the back gate electrode, the threshold voltage of the vertical channel transistor may also change, which may result in degradation of memory cell characteristics. Thus, a method of improving the stability of memory cells by controlling the back gate electrode is desirable.

### SUMMARY

Aspects of the inventive concept provide a memory device including a plurality of memory cells including a vertical channel transistor and configured to control back gate electrodes and a shielding bit line of the memory cells.

According to an aspect of the inventive concept, a memory device includes a plurality of memory blocks each including: a plurality of word lines extending in a first direction of the memory device, a plurality of back gate lines, each of the plurality of back gate lines being adjacent to a respective word line of the plurality of word lines, a plurality of bit lines extending in a second direction perpendicular to the first direction, and a shielding bit line arranged between adjacent bit lines of the plurality of bit lines and under the plurality of bit lines, wherein each of the plurality of memory blocks includes a mesh structure in which the plurality of back gate lines are electrically connected to the shielding bit line; and a voltage generator connected to the shielding bit line of each of the plurality of memory blocks, wherein the voltage generator is configured to drive the shielding bit line and the plurality of back gate lines of each of the plurality of memory blocks at the same voltage level.

According to another aspect of the inventive concept, a memory device includes a core peripheral circuit structure including first bonding metal pads; and a cell array structure overlapping the core peripheral circuit structure in a vertical direction and including second bonding metal pads respectively in contact with the first bonding metal pads, wherein the cell array structure includes a memory cell area including a plurality of memory blocks, each of the plurality of memory blocks including: a plurality of word lines extending in a first direction of the memory device, a plurality of back gate lines, each of the plurality of back gate lines being adjacent to a respective word line of the plurality of word lines, a plurality of bit lines extending in a second direction perpendicular to the first direction, and a shielding bit line arranged between adjacent bit lines of the plurality of bit lines and under the plurality of bit lines, wherein, in each of the plurality of memory blocks, the plurality of back gate lines are electrically connected to the shielding bit line, and the shielding bit line is in contact with the second bonding metal pads, the core peripheral circuit structure includes a voltage generator electrically connected to the first bonding metal pads, and the voltage generator is configured to drive the shielding bit line and the plurality of back gate lines of each of the plurality of memory blocks at the same voltage level.

According to another aspect of the inventive concept, a memory device includes a plurality of memory blocks each including: a plurality of word lines extending in a first direction of the memory device, a plurality of back gate lines, each of the plurality of back gate lines being adjacent to a respective word line of the plurality of word lines, a plurality of bit lines extending in a second direction perpendicular to the first direction, and a shielding bit line arranged between adjacent bit lines of the plurality of bit lines and under the plurality of bit lines; and a voltage generator configured to drive the shielding bit line and the plurality of back gate lines of each of the plurality of memory blocks at the same voltage level, wherein the voltage generator includes: a voltage generation circuit configured to generate, by using a power voltage of the memory device, an internal power voltage having the same voltage level as the power voltage, a bit line precharge voltage having a lower voltage level than the power voltage, and a negative voltage having a lower voltage level than a ground voltage of the memory device; a first driver configured to provide, to an internal power voltage line, the internal power voltage transmitted through a first switch connected to the voltage generation circuit; a second driver configured to provide, to a bit line precharge voltage line, the bit line precharge voltage transmitted through a second switch connected to the voltage generation circuit; and a third driver configured to provide, to the back gate lines and the shielding bit line, the negative voltage transmitted through a third switch connected to the voltage generation circuit, the voltage generator is configured to provide the ground voltage of the memory device to a ground voltage line, and each of the internal power voltage line, the bit line precharge voltage line, the negative voltage line, and the ground voltage line is electrically connected to the shielding bit line and the back gate lines of each of the plurality of memory blocks.

### BRIEF DESCRIPTION OF THE DRAWINGS

Embodiments will be more clearly understood from the following detailed description taken in conjunction with the accompanying drawings in which:

FIG. 1 is a conceptual diagram of a memory device according to some embodiments;

FIG. 2 is a diagram illustrating a configuration of the memory device of FIG. 1;

FIGS. 3, 4, 5, and 6 are each a diagram illustrating a structure of a memory device according to some embodiments;

FIG. 7 is a diagram of a voltage generator according to some embodiments;

FIG. 8 is a diagram illustrating a part of a memory cell array according to some embodiments;

FIG. 9 is a diagram illustrating an architecture of a voltage generator arranged in a memory device according to some embodiments;

FIG. 10 is a diagram illustrating characteristics of a memory device according to some embodiments; and

FIG. 11 is a block diagram of a system for illustrating an electronic apparatus including a memory device according to some embodiments.

### DETAILED DESCRIPTION OF THE EMBODIMENTS

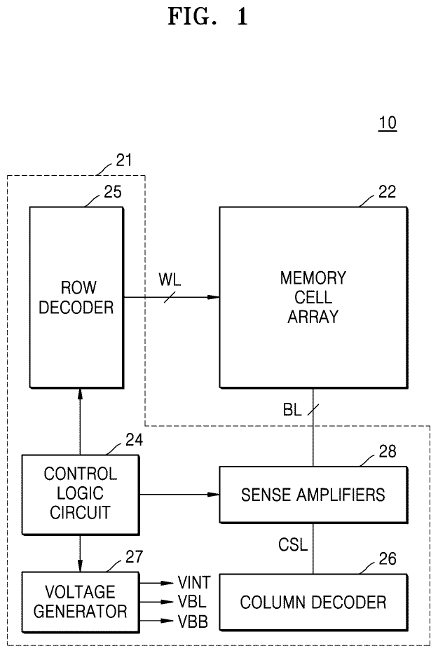

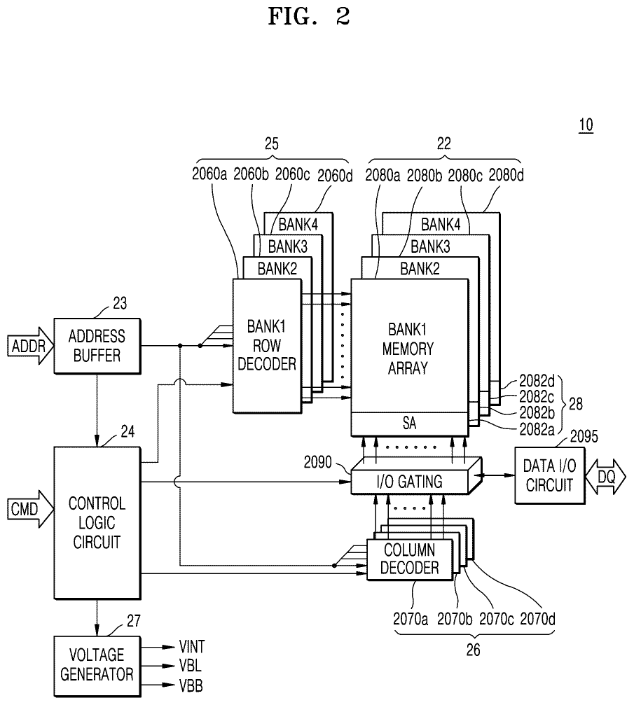

FIG. 1 is a conceptual diagram of a memory device according to some embodiments. FIG. 2 is a diagram illustrating a configuration of a memory device 10 of FIG. 1.

Referring to FIGS. 1 and 2, the memory device 10 may include a core peripheral circuit 21 and a memory cell array 22, and the core peripheral circuit 21 may include a control logic circuit 24, a voltage generator 27, a sense amplifier 28, a row decoder 25, and a column decoder 26. The core peripheral circuit 21 may further include an address buffer 23, an input/output (I/O) gating circuit 2090, a data I/O circuit 2095, etc. In embodiments of the inventive concept, the memory device 10 may be dynamic random access memory (DRAM) including a plurality of memory cells including a vertical channel transistor and a capacitor, and hereinafter, the “memory device” may refer to the DRAM.

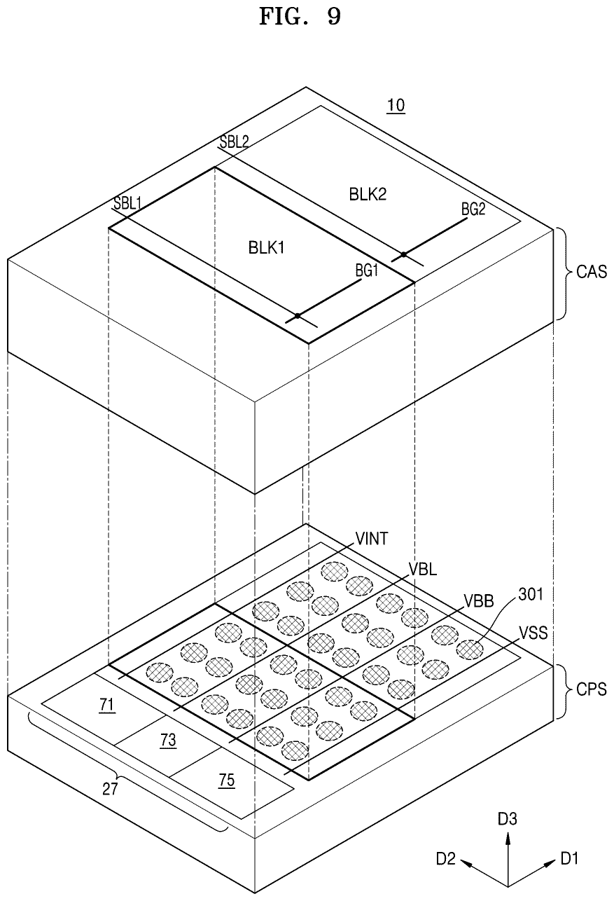

The memory cell array 22 may be connected to the row decoder 25 through word lines WL and may be connected to the sense amplifier 28 through bit lines BL. The memory cell array 22 may include a first bank array 2080a, a second bank array 2080b, a third bank array 2080c, and a fourth bank array 2080d. Each of the first to fourth bank arrays 2080a, 2080b, 2080c, and 2080d may include a plurality of word lines WL, a plurality of bit lines BL, and a plurality of memory cells formed at intersections of the plurality of word lines WL and the plurality of bit lines BL and may be divided into a plurality of memory blocks (BLK1 to BLKi), wherein i is an integer of 2 or greater (see, e.g., FIG. 9).

The voltage generator 27 may generate various internal voltages for driving circuits of the memory device 10. The voltage generator 27 may generate an internal power voltage VINT, a bit line precharge voltage VBL, a negative voltage VBB, a high voltage, a reference voltage, a bulk bias voltage, etc. by using a power voltage (for example, a primary power voltage VDD) of the memory device applied from the outside of the memory device 10.

For example, the high voltage may be provided to the row decoder 25, may have a higher voltage level than the power voltage VDD, and may be used in main word line drive signal generation circuits and sub-word line drive signal generation circuits for turning on an N-type metal oxide semiconductor (NMOS) cell transistor connected to the word lines WL. The internal power voltage VINT may have the same voltage level as the power voltage VDD and may be used as a sensing drive voltage of the sense amplifier 28. The sense amplifier 28 may sense and amplify a voltage difference between a bit line BL and a complementary bit line by using the sensing drive voltage. The bit line precharge voltage VBL may have a voltage level which corresponds to a half of a level of the internal power voltage VINT and may be used to equalize the bit line BL and the complementary bit line before the sense amplifier 28 senses the voltage difference between the bit line BL and the complementary bit line. The negative voltage VBB may have a negative (−) voltage level lower than the power voltage VDD and may be used to increase data retention time by raising a threshold voltage Vth of the NMOS transistor. The negative voltage VBB may be applied to a well area in which the NMOS transistor is formed and may commonly be referred to as a bulk bias voltage or a back bias voltage. The reference voltage may be used for comparison with a voltage of a signal received from a command/address bus to determine a logic value of a signal received from a memory controller.

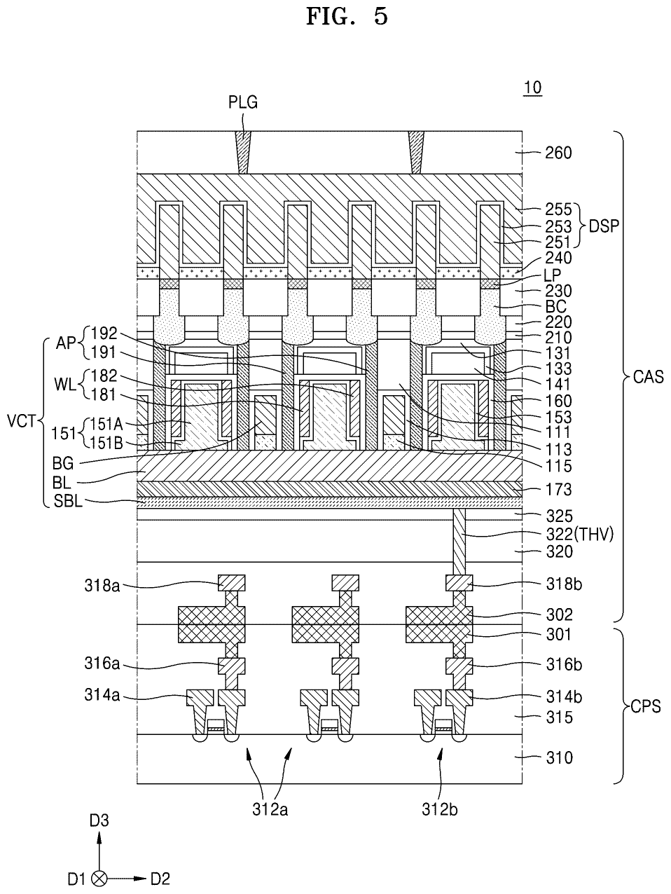

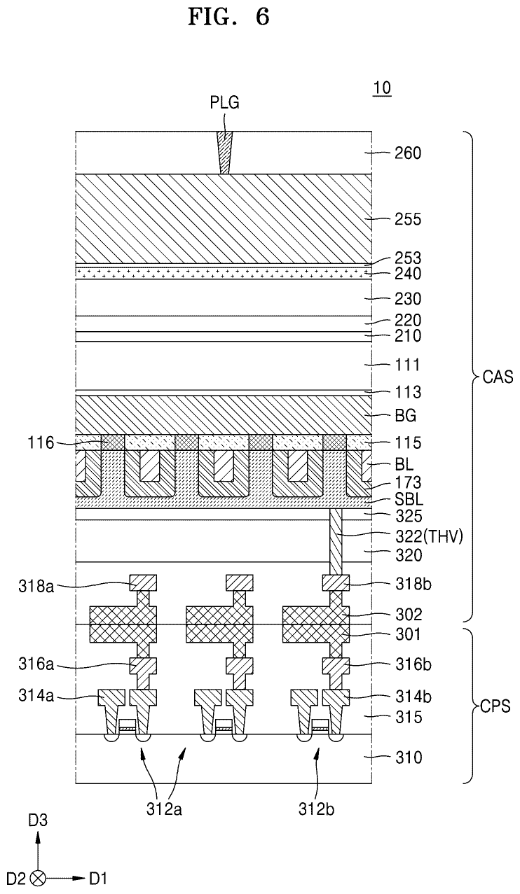

In some embodiments, the internal power voltage VINT, the bit line precharge voltage VBL, and/or the negative voltage VBB generated by the voltage generator 27 may be commonly provided to a back gate line BG (or back gate electrodes, e.g., FIGS. 5 and 6) and a shielding bit line SBL of the memory cell array 22. This is to prevent a voltage change of the back gate line BG by using the large capacitance of the shielding bit line SBL (see, e.g., FIGS. 5 and 6) arranged between the bit lines BL and under the bit lines BL of the memory cell array 22.

The row decoder 25 may include a first bank row decoder 2060a, a second bank row decoder 2060b, a third bank row decoder 2060c, and a fourth bank row decoder 2060d respectively connected to the first to fourth bank arrays 2080a, 2080b, 2080c, and 2080d, and the column decoder 26 may include a first bank column decoder 2070a, a second bank column decoder 2070b, a third bank column decoder 2070c, and a fourth bank column decoder 2070d respectively connected to the first to fourth bank arrays 2080a, 2080b, 2080c, and 2080d. The sense amplifier 28 may include a first sense amplifier 2082a, a second sense amplifier 2082b, a third sense amplifier 2082c, a fourth sense amplifier 2082d respectively connected to the first to fourth bank arrays 2080a, 2080b, 2080c, and 2080d.

The first to fourth bank arrays 2080a, 2080b, 2080c, and 2080d, the first to fourth bank row decoders 2060a, 2060b, 2060c, and 2060d, the first to fourth bank column decoders 2070a, 2070b, 2070c, and 2070d, and the first to fourth sense amplifiers 2082a, 2082b, 2082c, and 2082d may constitute first to fourth banks. The first to fourth bank row decoders 2060a, 2060b, 2060c, and 2060d, the first to fourth bank column decoders 2070a, 2070b, 2070c, and 2070d, and the first to fourth sense amplifiers 2082a, 2082b, 2082c, and 2082d may be referred to as core circuits of the first to fourth banks BANK1 to BANK4. Although the embodiment describes an example in which the memory device 10 includes four banks, in some embodiments, the memory device 10 may include various numbers of banks.

The address buffer 23 may receive an address ADDR including a row address and a column address from the memory controller connected to the memory device 10. In addition, the address buffer 23 may receive a bank address and provide the same to a bank control logic, provide a received row address to the row decoder 25, and provide a received column address to the column decoder 26. The bank control logic may generate bank control signals in response to a bank address. In response to the bank control signals, among the first to fourth bank row decoder 2060a, 2060b, 2060c, and 2060d, a bank row decoder corresponding to the bank address may be activated, and among the first to fourth bank column decoder 2070a, 2070b, 2070c, and 2070d, a bank column decoder corresponding to the bank address may be activated.

The control logic circuit 24 may control overall operations of the memory device 10. The control logic circuit 24 may generate control signals to perform a write operation and/or a read operation of the memory device 10. The control logic circuit 24 may include a mode register for setting a plurality of operation options of the memory device 10 and a command decoder decoding a command CMD received from the memory controller.

The sense amplifier 28 may sense data stored in the memory cell and transmit the sensed data to the data I/O circuit 2095 to output the same to the memory controller through data pad(s). The data I/O circuit 2095 may receive data to be written to the memory cells from the memory controller through the data pad(s) and transmit the same to the memory cell array 22. The I/O gating circuit 2090 may output read data by using a data line amplifier configured to receive and amplify data sensed by the sense amplifier 28. The read data may be output to the memory controller through the data pad(s). The I/O gating circuit 2090 may include a column select circuit, an input data mask logic, read data latches for storing the read data output from the first to fourth bank arrays 2080a, 2080b, 2080c, and 2080d, and a write driver for writing data to the first to fourth bank arrays 2080a, 2080b, 2080c, and 2080d, in addition to circuits gating I/O data DQ.

The read data output from a bank array from among the first to fourth bank arrays 2080a, 2080b, 2080c, and 2080d may be sensed by a sense amplifier 2082 corresponding to the bank array and be stored in the read data latches. The write data to be written to a memory cell array of a bank array from among the first to fourth bank arrays 2080a, 2080b, 2080c, and 2080d may be provided to the data I/O circuit 2095 from the memory controller. The data provided to the data I/O circuit 2095 may be written to a bank array through a write driver.

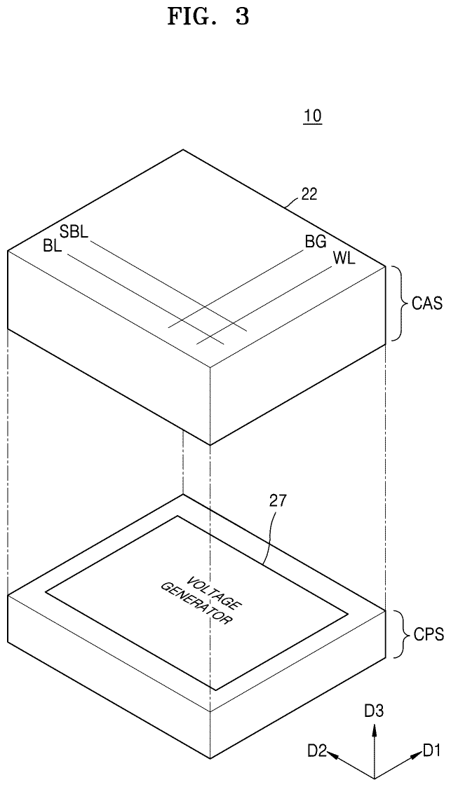

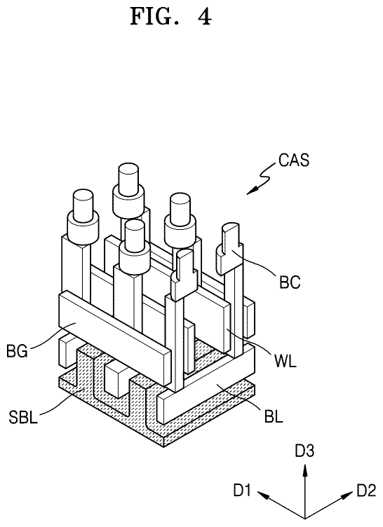

FIGS. 3, 4, 5, and 6 are each a diagram illustrating a structure of a memory device according to some embodiments. FIG. 4 is a perspective view of a cell array structure CAS of the memory device 10 of FIG. 3. FIG. 5 is a cross-sectional view illustrating a cross-section cut along a direction corresponding to a second direction D2 in the perspective view of memory device 10 illustrated in FIG. 4, and FIG. 6 is a cross-section cut along a direction corresponding to a first direction D1. For convenience in understanding, portions illustrated by using such terms as “upper surface/lower surface,” “upper portion/lower portion,” “on/under,” etc., are described based on the directions indicated in the drawings. Accordingly, a surface may be referred to as both an upper surface and a lower surface according to a direction indicated in the drawing.

Referring to FIGS. 2 and 3, the memory device 10 may include the cell array structure CAS and a core peripheral circuit structure CPS which overlap each other in a third direction (D3 direction). The cell array structure CAS may include the memory cell array 22. The core peripheral circuit structure CPS may include a core peripheral circuit including the address buffer 23, the control logic circuit 24, the row decoder 25, the column decoder 26, the sense amplifier 28, the I/O gating circuit 2090, and the data I/O circuit 2095. For the sake of brevity in drawings, it is illustrated in the drawings that the circuits constituting the voltage generator 27 are arranged in the core peripheral circuit structure CPS. The memory device 10 may have a structure in which the memory cell array 22 is arranged on the core peripheral circuit, that is, a cell over periphery (COP) structure.

The cell array structure CAS may include a plurality of memory cells including a vertical channel transistor VCT. In the cell array structure CAS, the plurality of word lines WL may extend in the first direction (D1 direction), and the plurality of bit lines BL may extend in the second direction (D2 direction). A plurality of back gate lines BG may be arranged adjacent to the plurality of word lines WL, and a plurality of shielding bit lines SBL may be arranged adjacent to the plurality of bit lines BL. For example, each word line WL may be arranged adjacent to a respective back gate line BG of the plurality of back gate lines BG. For example, the plurality of bit lines BL and the plurality of shielding bit lines SBL may be arranged in an alternating fashion such that each bit line BL is between two shielding bit lines SBL and each shielding bit line SBL is between two bit lines BL. See, e.g., FIG. 4.

The core peripheral circuit structure CPS may include a semiconductor substrate, and the core peripheral circuit may be formed by forming semiconductor elements such as a transistor and patterns for wiring the elements on the semiconductor substrate. After the core peripheral circuit is formed in the core peripheral circuit structure CPS, the cell array structure CAS including the memory cell array 22 may be formed, and patterns for electrically connecting the core peripheral circuit formed in the core peripheral circuit structure CPS to the shielding bit lines SBL, the bit lines BL, the back gate line BG, and the word lines WL of the memory cell array 22 (for example, bonding metal pads 301 and 302 of FIG. 5) may be formed. For convenience in explanation, both of the term “back gate line BG” and the term “back gate electrode BG” may be used throughout the specification.

Referring to FIGS. 4, 5, and 6, the core peripheral circuit structure CPS may include a lower substrate 310, an interlayer insulating layer 315, a plurality of circuit elements 312a and 312b formed on the lower substrate 310, first metal layers 314a and 314b connected to each of the plurality of circuit elements 312a and 312b, second metal layers 316a and 316b formed on the first metal layers 314a and 314b, and a bonding metal pad 301 formed on the uppermost metal layer of the core peripheral circuit structure CPS. In an embodiment, the first metal layers 314a and 314b may be formed of or include tungsten which has a relatively high resistance, the second metal layers 316a and 316b may be formed of or include copper which has a relatively low resistance, and the bonding metal pad 301 may be formed of or include copper. In another embodiment, the bonding metal pad 301 may be formed of or include aluminum (Al) or tungsten (W).

Although the specification describes and illustrates only the first metal layers 314a and 314b and the second metal layers 316a and 316b, the inventive concept is not limited thereto, and at least one metal layer may be further formed on the second metal layers 316a and 316b. Some of the at least one metal layer formed on the second metal layers 316a and 316b may be formed of or include aluminum, etc. having a lower resistance than copper forming the second metal layers 316a and 316b. The interlayer insulating layer 315 may be arranged on the lower substrate 310 to cover the plurality of circuit elements 312a and 312b, the first metal layers 314a and 314b, and the second metal layers 316a and 316b, and may be formed of or include an insulating material such as a silicon oxide, a silicon nitride, etc.

The plurality of circuit elements 312a and 312b may be connected to at least one of circuit elements constituting a peripheral circuit. For convenience in explanation, the first circuit element 312a may represent a transistor constituting the row decoder 25, and the second circuit element 312b may represent a transistor constituting the voltage generator 27.

In the memory device 10, the bit lines BL may be arranged apart from each other in the first direction D1 on an upper substrate 320. The upper substrate 320 may be formed of the same material as that of the lower substrate 310. According to an embodiment, the upper substrate 320 may be referred to as a plate or a conductive plate. The bit lines BL may be arranged apart from each other in the first direction D1, and may extend in the second direction D2 intersecting with the first direction D1. Active patterns AP may be alternately arranged in the second direction D2 on each of the bit lines BL. The active patterns AP may be arranged apart from each other in the first direction D1. That is, the active patterns AP may be arranged in a two-dimensional (2D) manner in the first direction D1 and the second direction D2 which intersect with each other. In some embodiments, the plurality of word lines WL, the plurality of bit lines BL, and the plurality of active patterns AP may constitute a plurality of vertical channel transistors.

Each of the active patterns AP may have a length in the first direction D1, a width in the second direction D2, and a height in the third direction D3 perpendicular to a surface of the upper substrate 320. The active patterns AP may have a substantially uniform width. Each of the active patterns AP may have an upper surface and a lower surface which face each other in the third direction D3. For example, the lower surface of the active patterns AP may be in contact with the bine line BL. Each of the active patterns AP may include a source region adjacent to the bit line BL, a drain region adjacent to a contact pattern BC, and a channel region between the source region and the drain region. The channel region of the active patterns AP may be controlled by the word lines WL and the back gate electrodes BG during the operation of the memory device 10. The active patterns AP may be formed of or include, for example, single-crystal silicon (Si) to improve leakage current characteristics during the operation of the memory device 10.

The back gate electrodes BG may be arranged apart from each other in the second direction D2 on the bit lines BL. The back gate electrodes BG may extend in the first direction D1, crossing the bit lines BL. Each of the back gate electrodes BG may be arranged between neighboring active patterns AP in the second direction D2. A first active pattern 191 may be arranged on one side of each of the back gate electrodes BG, and a second active pattern 192 may be arranged on the other side. The back gate electrodes BG may have a height less than a height of the active patterns AP in the vertical direction. During the operation of the memory device 10, a negative voltage may be applied to the back gate electrodes BG, and the back gate electrodes BG may increase the threshold voltage of the vertical channel transistor. This means that degradation of leakage current characteristics due to the reduced threshold voltage according to the miniaturization of the vertical channel transistor may be prevented.

A first insulating pattern 111 may be arranged between the active patterns AP adjacent to each other in the second direction D2. The first insulating pattern 111 may extend in parallel with the back gate electrodes BG in the first direction D1. A back gate insulating film 113 may be arranged between the back gate electrode BG and the active patterns AP and between the back gate electrode BG and the first insulating pattern 111. The back gate insulating film 113 may include vertical portions covering both sides of the back gate electrode BG and a horizontal portion connecting the vertical portions to each other. The horizontal portion of the back gate insulating film 113 may be closer to the contact pattern BC than to the bit line BL and may cover an upper surface of the back gate electrode BG as shown, e.g., in FIGS. 5 and 6. A back gate capping pattern 115 may be arranged between the bit lines BL and the back gate electrode BG. The back gate capping pattern 115 may be formed of or include an insulating material, and a lower surface of the back gate capping pattern 115 may be in contact with the bit lines BL. The back gate capping pattern 115 may be arranged between the vertical portions of the back gate insulating film 113.

The word lines WL may extend on the bit lines BL in the first direction D1 and may be arranged alternately in the second direction D2. A first word line 181 from among the word lines WL may be arranged on one side of the first active pattern 191, and a second word line 182 from among the word lines WL may be arranged on another side of the second active pattern 192. A part of the first word lines 181 may be arranged between the first active patterns 191 adjacent to each other in the first direction D1, and a part of the second word lines 182 may be arranged between the second active patterns 192 adjacent to each other in the first direction D1.

The word lines WL may be arranged vertically apart from the bit lines BL and the contact patterns BC. From the vertical perspective (e.g., in a plan view), the word lines WL may be arranged between the bit lines BL and the contact patterns BC. Neighboring word lines WL may have sidewalls facing each other. The word lines WL may have a height less than the height of the active patterns AP in the vertical direction. The height of the word lines WL may be greater than or equal to the height of the back gate electrodes BG in the third direction D3.

Gate insulating films 160 may be arranged between the word lines WL and the active patterns AP. The gate insulating films 160 may extend in parallel with the word lines WL in the first direction D1. The gate insulating film 160 may cover one side of the first active pattern 191 and another side of the second active pattern 192. The gate insulating film 160 may have a substantially uniform thickness. A second insulating pattern 141 may be arranged between the gate insulating film 160 and the contact patterns BC. For example, the second insulating pattern 141 may be formed of or include a silicon oxide. A first etch stop film 131 and a second etch stop film 133 may be arranged between the active patterns AP and the second insulating pattern 141.

On the gate insulating film 160, the word lines WL may be separated from each other by a third insulating pattern 151. The third insulating pattern 151 may extend in the first direction D1 between the word lines WL. A first capping film 153 may be arranged between the third insulating pattern 151 and the word lines WL. The first capping film 153 may have a substantially uniform thickness. The third insulating pattern 151 may include a third vertical pattern 151A and a third horizontal pattern 151B.

The contact patterns BC may pass through a third etch stop film 210 and an interlayer insulating film 220 and may be connected to each of the active patterns AP. In other words, the contact patterns BC may be connected to each of the drain regions of the active patterns AP. The contact patterns BC may have a lower width greater than an upper width. The contact patterns BC adjacent to each other may be separated from each other by isolation insulating patterns 230. From a planar perspective, each of the contact patterns BC may have various shapes, such as a circular shape, an elliptical shape, a rectangular shape, a square shape, a rhombic shape, a hexagonal shape, etc. Landing pads LP may be arranged on the contact patterns BC.

The isolation insulating patterns 230 may be arranged between the landing pads LP. From the planar perspective, the landing pads LP may be arranged in a matrix form in the first direction D1 and the second direction D2. Upper surfaces of the landing pads LP may be substantially coplanar with upper surfaces of the isolation insulating patterns 230. A fourth etch stop film 240 may be formed on the isolation insulating patterns 230.

Data storage patterns DSP may be arranged on the landing pads LP. The data storage patterns DSP may be electrically connected to the active patterns AP. The data storage patterns DSP may be arranged in a matrix form in the first direction D1 and the second direction D2. The data storage patterns DSP may completely or partially overlap the landing pads LP. The data storage patterns DSP may be in contact with all or a part of the upper surfaces of the landing pads LP. An upper insulating film 260 may be arranged on the data storage patterns DSP, and cell contact plugs PLG may pass through the upper insulating film 260 and may be connected to a plate electrode 255.

In some embodiments, the data storage patterns DSP may be a capacitor, and may include a capacitor dielectric film 253 arranged between the plate electrode 255 and storage electrodes 251. In this case, the storage electrode 251 may be in direct contact with the landing pad LP, and from the planar perspective, the storage electrode 251 may have various shapes, such as a circular shape, an elliptical shape, a rectangular shape, a square shape, a rhombic shape, a hexagonal shape, etc.

In some embodiments, the data storage patterns DSP may be a variable resistance pattern which may be switched between two resistance states by an electrical pulse applied to a memory element. For example, the data storage patterns DSP may be formed of or include a phase-change material of which crystalline state changes according to a current amount, a perovskite compound, a transition metal oxide, a magnetic material, a ferromagnetic material, an antiferromagnetic material, etc.; however, the inventive concept is not limited thereto. According to a material film of the data storage patterns DSP, the memory device 10 may be implemented as resistive memory such as phase change random access memory (PRAM), magnetic RAM (MRAM), resistive RAM (RRAM), etc.

The shielding bit line SBL may be arranged between the bit lines BL and under the bit lines BL. The shielding bit line SBL may reduce the coupling noise between the bit lines BL adjacent to each other. For example, the shielding bit line SBL may be a shielding structure that is formed of or includes a conductive material. First line insulating layers 173 may be arranged apart from each other in the first direction D1 and may extend in the second direction D2. The first line insulating layers 173 may be in contact with the facing sidewalls of the neighboring bit lines BL and may be separated from each other in the first direction D1. For example, each first line insulating layer 173 may be in contact with both sidewalls and a bottom surface of a respective bit line BL as shown, e.g., in FIG. 6. A second line insulating layer 325 may cover a lower surface and a lateral surface of the shielding bit line SBL and may fill a space between the shielding bit lines SBL. The shielding bit line SBL may pass through the back gate capping pattern 115 and may be connected to each of the back gate electrodes BG.

A through electrode 322 may pass through the upper substrate 320 and be in contact with a metal layer 318b and extend in the third direction (D3 direction) to a bonding metal pad 302 formed on the uppermost metal layer of the core peripheral circuit structure CPS. Although the embodiment describes and illustrates one metal layer (318a and 318b), the inventive concept is not limited thereto, and at least one metal layer may be further formed on the metal layer (318a and 318b). The shielding bit line SBL may be electrically connected to an element 312b of the voltage generator 27 through the bonding metal pad 302 of the cell array structure CAS and the bonding metal pad 301 of the core peripheral circuit structure CPS. The shielding bit line SBL may be connected to the voltage generator 27 and may be controlled by the control logic circuit.

In some embodiments, the bonding metal pad 302 of the cell array structure CAS and the bonding metal pad 301 of the core peripheral circuit structure CPS may be connected to each other by an electrical or physical bonding method. When the bonding metal pads 301 and 302 include copper (Cu), the bonding method may be a Cu-Cu bonding method. In another embodiment, the bonding metal pads 301 and 302 may be formed of or include aluminum (Al) or tungsten (W).

The metal layer 318a of the cell array structure CAS may be electrically or physically connected to each of the word lines WL and may be in contact with the bonding metal pad 301. Each of the word lines WL may be electrically connected to an element 312a of the row decoder 25 through the bonding metal pad 302 of the cell array structure CAS and the bonding metal pad 301 of the core peripheral circuit structure CPS. Hereinafter, components and operations of the voltage generator 27 connected to the back gate lines BG and the shielding bit line SBL are described in detail in relation to various embodiments.

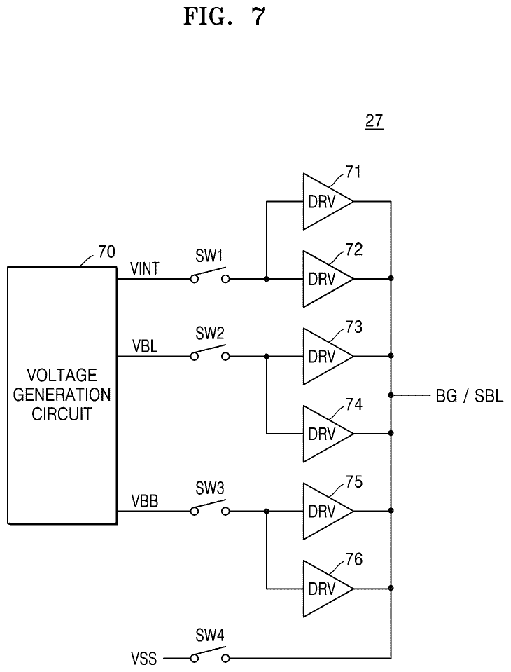

FIG. 7 is a diagram of a voltage generator according to some embodiments.

Referring to FIG. 7, the voltage generator 27 may include a voltage generation circuit 70, a plurality of switches SW1, SW2, SW3, and SW4, and a plurality of driver circuits 71, 72, 73, 74, 75, and 76. The voltage generation circuit 70 may generate the internal power voltage VINT, the bit line precharge voltage VBL, and the negative voltage VBB by using a power voltage (for example, VDD) of the memory device 10. The internal power voltage VINT may be provided to a first driver circuit 71 and a second driver circuit 72 through a first switch SW1. The first and second driver circuits 71 and 72 may be commonly connected to the back gate lines BG and the shielding bit line SBL. The back gate lines BG and the shielding bit line SBL may have a level of the internal power voltage VINT. Although the back gate lines BG and the shielding bit line SBL of the memory cell array 22 are described as being driven at a level of the internal power voltage VINT according to the configuration of two driver circuits 71 and 72, the inventive concept is not limited thereto, and various numbers of driver circuits may be included.

The bit line precharge voltage VBL may be provided to a third driver circuit 73 and a fourth driver circuit 74 through a second switch SW2. The third and fourth driver circuits 73 and 74 may be commonly connected to the back gate lines BG and the shielding bit line SBL. The back gate lines BG and the shielding bit line SBL may have a level of the bit line precharge voltage VBL. Although the back gate lines BG and the shielding bit line SBL of the memory cell array 22 are described as being driven at a level of the bit line precharge voltage VBL according to the configuration of two driver circuits 73 and 74, the inventive concept is not limited thereto, and various numbers of driver circuits may be included.

The negative voltage VBB may be provided to a fifth driver circuit 75 and a sixth driver circuit 76 through a third switch SW3. The fifth and the sixth driver circuits 75 and 76 may be commonly connected to the back gate lines BG and the shielding bit line SBL. The back gate lines BG and the shielding bit line SBL may have a level of the negative voltage VBB. Although the back gate lines BG and the shielding bit line SBL of the memory cell array 22 are described as being driven at a level of the negative voltage VBB according to the configuration of two driver circuits 75 and 76, the inventive concept is not limited thereto, and various numbers of driver circuits may be included.

The voltage generator 27 may commonly provide a ground voltage VSS to the back gate lines BG and the shielding bit line SBL through a fourth switch SW4.

In some embodiments, the control logic circuit 24 may control the plurality of switches SW1, SW2, SW3, and SW4 to turn on one of the switches, and through the turned-on switch, a voltage generated in the voltage generation circuit 70 may be provided to the back gate lines BG and the shielding bit line SBL.

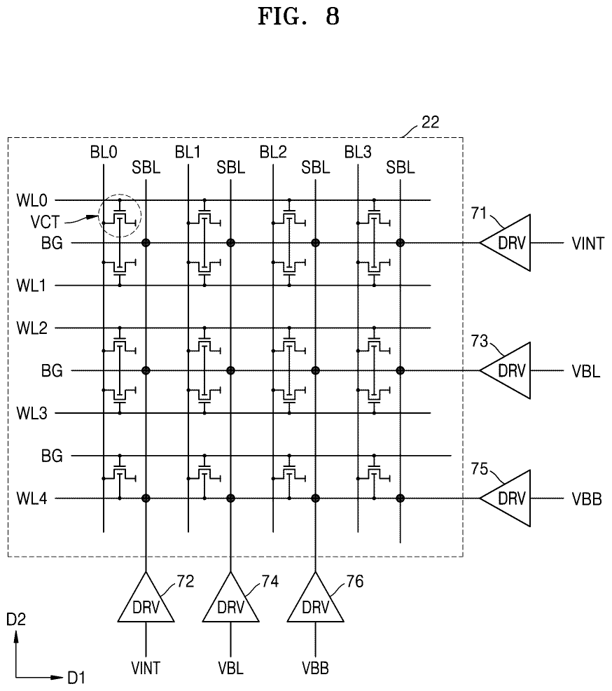

FIG. 8 is a diagram illustrating a part of the memory cell array 22 according to some embodiments.

FIGS. 7 and 8 illustrate the vertical channel transistor VCT of each of the memory cells formed at intersections of a plurality of word lines WL0 to WL4 and a plurality of bit lines BLO to BL3 and a mesh structure in which the back gate line BG and the shielding bit line SBL are connected to each other in the memory cell array 22. The first driver circuit 71, the third driver circuit 73, and the fifth driver circuit 75 may be arranged on one side of the memory cell array 22 in the first direction (D1 direction) in which the plurality of word lines WL0 to WL4 extend. The second driver circuit 72, the fourth driver circuit 74, and the sixth driver circuit 76 may be arranged on another side of the memory cell array 22 in the second direction (D2 direction) in which the plurality of bit lines BL0 to BL3 extend.

The embodiment describes the configuration in which the plurality of driver circuits 71 to 76 are arranged on sides of the memory cell array 22 in the first direction (D1 direction) and the second direction (D2 direction). However, this is only an example provided to facilitate the understanding thereof, and is not intended to limit the inventive concept. The plurality of driver circuits 71 to 76 may be arranged on any one or more of the sides of the memory cell array 22 in the first direction (D1 direction) and the second direction (D2 direction), and a voltage output from each of the plurality of driver circuits 71 to 76 may be provided to the shielding bit line SBL and the back gate line BG in a mesh structure. As the plurality of driver circuits 71 to 76 arranged on both sides of the memory cell array 22 in the first direction (D1 direction) and the second direction (D2 direction) have a great driving ability, a voltage level of the shielding bit line SBL and the back gate line BG in a mesh structure may be more stable.

The first and second driver circuits 71 and 72 may provide the internal power voltage VINT to the back gate line BG and the shielding bit line SBL. The third and fourth driver circuits 73 and 74 may provide the bit line precharge voltage VBL to the back gate line BG and the shielding bit line SBL. The fifth and sixth driver circuits 75 and 76 may provide the negative voltage VBB to the back gate line BG and the shielding bit line SBL.

In some embodiments, in the memory cell array 22, the fourth switch SW4 may be arranged on one side of the memory cell array 22 in the first direction (D1 direction) in which the plurality of word lines WL0 to WL4 extend, and the fourth switch SW4 may also be arranged on another side of the memory cell array 22 in the second direction (D2 direction) in which the plurality of bit lines BL0 to BL3 extend. By the fourth switch SW4, the ground voltage VSS may be provided to the shielding bit line SBL and the back gate line BG having a mesh structure.

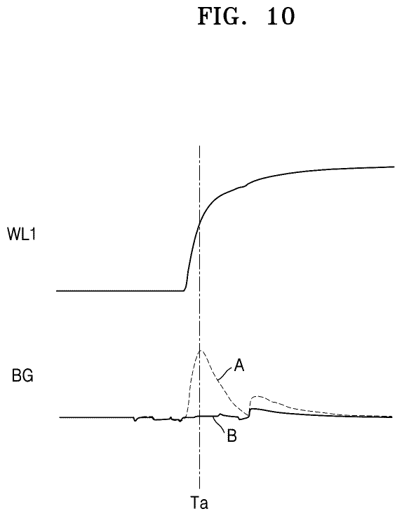

FIG. 9 is a diagram illustrating an architecture of a voltage generator arranged in a memory device according to some embodiments. FIG. 10 is a diagram illustrating characteristics of a memory device according to some embodiments. For the sake of brevity in drawings, FIG. 9 illustrates a first memory block BLK1 and a second memory block BLK2 from among the plurality of memory blocks BLK1 to BLKi included in the first to fourth banks BANK1, BANK2, BANK3, and BANK4 of FIG. 2. The back gate lines BG and the shielding bit line SBL of the first memory block BLK1 (hereinafter, denoted by “BG1” and “SBL1,” respectively) are described as being electrically connected to each other, and the back gate lines BG and the shielding bit line SBL of the second memory block BLK2 (hereinafter, denoted by “BG2” and “SBL2,” respectively) are described as being electrically connected to each other (the connection points in the respective memory blocks BLK1 and BLK2 are marked with dots).

Referring to FIG. 9 in relation to FIGS. 5, 6, 7, and 8, the memory device 10 may include the cell array structure CAS and the core peripheral circuit structure CPS which overlap each other in the third direction (D3 direction). The cell array structure CAS may include a first memory block BLK1 area and a second memory block BLK2 area. The core peripheral circuit structure CPS may include a voltage generator 27 area connected commonly to the first and second memory blocks BLK1 and BLK2, and the bonding metal pads 301. The voltage generator 27 area may include the driver circuits (71, 73, and 75) respectively outputting the internal power voltage VINT, the bit line precharge voltage VBL, and the negative voltage VBB. Each of a ground voltage VSS line as well as a negative voltage VBB line, a bit line precharge voltage VBL line, and an internal power voltage VINT line respectively connected to the driver circuits (71, 73, and 75) may be selectively connected to the bonding metal pads 301.

The bonding metal pad 301 of the core peripheral circuit structure CPS may be in contact with the bonding metal pad 302 of the cell array structure CAS. The bonding metal pad 302 of the cell array structure CAS may be electrically connected to a first shielding bit line SBL1 of the first memory block BLK1 and a second shielding bit line SBL2 of the second memory block BLK2. The first shielding bit line SBL1 of the first memory block BLK1 may be electrically or physically connected to a first back gate line BG1, and the second shielding bit line SBL2 of the second memory block BLK2 may be electrically or physically connected to a second back gate line BG2.

In some embodiments, the first shielding bit line SBL1 and the first back gate line BG1 of the first memory block BLK1 may be driven at the same voltage level as the second shielding bit line SBL2 and the second back gate line BG2 of the second memory block BLK2 by the control logic circuit 24 of FIG. 2. For example, the first and second back gate lines BG1 and BG2 and the first and second shielding bit lines SBL1 and SBL2 may all be driven at an internal power voltage VINT level, a bit line precharge voltage VBL level, a negative voltage VBB level, or a ground voltage VSS level.

In some embodiments, the first shielding bit line SBL1 and the first back gate line BG1 of the first memory block BLK1 may be driven at a voltage level different from that of the second shielding bit line SBL2 and the second back gate line BG2 of the second memory block BLK2 by the control logic circuit 24 of FIG. 2. For example, the first shielding bit line SBL1 and the first back gate line BG1 of the first memory block BLK1 may be driven at the internal power voltage VINT level, and at the same time, the second shielding bit line SBL2 and the second back gate line BG2 of the second memory block BLK2 may be driven at least one of the bit line precharge voltage VBL level, the negative voltage VBB level, and the ground voltage VSS level. As another example, the first shielding bit line SBL1 and the first back gate line BG1 of the first memory block BLK1 may be driven at the bit line precharge voltage VBL level, and at the same time, the second shielding bit line SBL2 and the second back gate line BG2 of the second memory block BLK2 may be driven at least one of the internal power voltage VINT level, the negative voltage VBB level, and the ground voltage VSS level. As another example, the first shielding bit line SBL1 and the first back gate line BG1 of the first memory block BLK1 may be driven at the negative voltage VBB level, and at the same time, the second shielding bit line SBL2 and the second back gate line BG2 of the second memory block BLK2 may be driven at least one of the internal power voltage VINT level, the bit line precharge voltage VBL level, and the ground voltage VSS level. As another example, the first shielding bit line SBL1 and the first back gate line BG1 of the first memory block BLK1 may be driven at the ground voltage VSS level, and at the same time, the second shielding bit line SBL2 and the second back gate line BG2 of the second memory block BLK2 may be driven at least one of the internal power voltage VINT level, the bit line precharge voltage VBL level, and th negative voltage VBB level.

FIGS. 8 and 10 show voltage levels of the back gate line BG adjacent to the word line WL1 selected from among the plurality of word lines WL0 to WL4 of the memory cell array 22 when the selected word line WL1 is enabled to a high voltage level at a time point Ta. A waveform A represents a voltage level of the back gate line BG when the back gate line BG is not electrically connected to the shielding bit line SBL, and a waveform B represents a voltage level of the back gate line BG when the back gate line BG is electrically connected to the shielding bit line SBL. The waveform A shows a change in the voltage level of the back gate line BG coupled to a high voltage level of the selected word line WL1. The waveform B shows a negligible voltage change of the back gate line BG which has not been coupled to the high voltage level of the selected word line WL1. This means that as the back gate line BG is coupled to a large-capacity capacitor of the shielding bit line SBL (see FIGS. 5 and 6) arranged between the bit lines BL of the memory cell array 22 and under the bit lines BL and is maintained at a particular voltage level provided from the voltage generator 27 (for example, the internal power voltage VINT level, the bit line precharge voltage VBL level, or the ground voltage VSS level), the voltage level of the back gate line BG may be stable. Accordingly, a change in the threshold voltage of the vertical channel transistor VCT may be prevented, which leads to improved stability of memory cells and improved performance of DRAM.

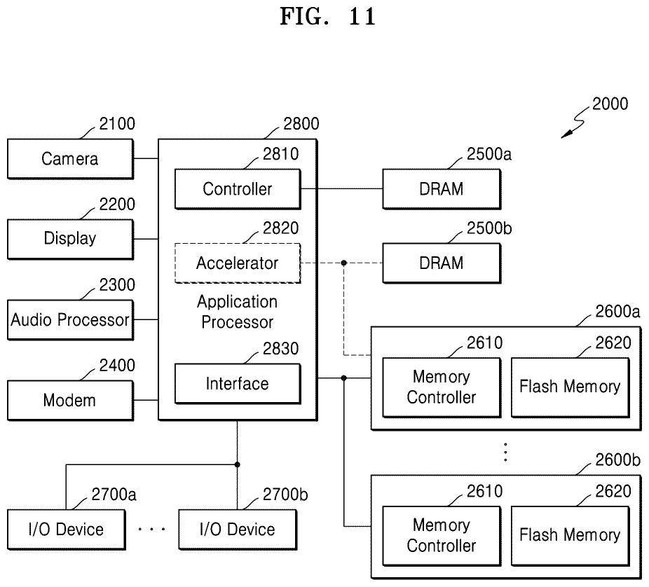

FIG. 11 is a block diagram of a system 2000 for illustrating an electronic apparatus including a memory device according to some embodiments.

Referring to FIG. 11, the system 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The system 2000 may be implemented as a laptop computer, a mobile phone, a smart phone, a tablet personal computer (PC), a wearable device, a healthcare device, an Internet of Things (IoT) device, or the like. The system 2000 may also be implemented as a server or a personal computer.

The camera 2100 may take a still picture or film a video according to the control by a user and may store the taken image or filmed video data or transmit the same to the display 2200. The audio processor 2300 may process audio data included in the flash memories 2600a and 2600b or contents of a network. The modem 2400 may modulate and transmit a signal to transmit/receive wired/wireless data and may demodulate a modulated signal to restore the same to an original signal at a receiving side. The I/O devices 2700a and 2700b may include devices providing digital input and/or output functions, such as a universal serial bus (USB), a storage, a digital camera, a secure digital (SD) card, a digital versatile disc (DVD), a network adapter, a touch screen, etc.

The AP 2800 may control the overall operations of the system 2000. The AP 2800 may include a control block 2810 (e.g., a controller), an accelerator block or accelerator chip 2820, and an interface block 2830. The AP 2800 may control the display 2200 such that some of contents stored in the flash memories 2600a and 2600b are displayed on the display 2200. When a user input is received through the I/O devices 2700a and 2700b, the AP 2800 may perform a control operation corresponding to the user input. The AP 2800 may include an accelerator block, which is a dedicated circuit for artificial intelligence (AI) data operation, or may include the accelerator chip 2820 separately from the AP 2800. The DRAM 2500b may be additionally mounted to the accelerator block or accelerator chip 2820. The accelerator is a functional block that professionally performs a specific function of the AP 2800, and the accelerator may include a GPU, which is a functional block that professionally performs graphic data processing, a neural processing unit (NPU), which is a block that professionally performs AI computation and inference, and a data processing unit (DPU), which is a block that professionally performs data transmission.

The system 2000 may include the plurality of DRAMs 2500a and 2500b. The AP 2800 may control the DRAMs 2500a and 2500b through a command and mode register (MRS) setting conforming to the Joint Electron Device Engineering Council (JEDEC) standard, or may set DRAM interface protocols and perform communication to use company-specific functions such as low voltage/high speed/reliability and cyclic redundancy check (CRC) or error correction code (ECC) function. For example, the AP 2800 may communicate with the DRAM 2500a through an interface conforming to the JEDEC standards such as LPDDR4, LPDDR5, etc., and the accelerator block or accelerator chip 2820 may establish a new DRAM interface protocol and perform communication to control the DRAM 2500b for accelerators, which has a higher bandwidth than the DRAM 2500a.

In FIG. 11, only the DRAMs 2500a and 2500b are illustrated, but the inventive concept is not limited thereto, and when bandwidth, response speed, and voltage conditions of the AP 2800 or accelerator chip 2820 are satisfied, any memory such as PRAM, SRAM, MRAM, RRAM, FRAM or Hybrid RAM memory may be used. The DRAMs 2500a and 2500b may have relatively smaller latency and bandwidth than the I/O devices 2700a and 2700b or the flash memories 2600a and 2600b. The DRAMs 2500a and 2500b may be initialized when the system 2000 is powered on. When an operating system and application data are loaded, the DRAMs 2500a and 2500b may be used as a temporary storage for the operating system and application data or may be used as an execution space for various software codes.

In the DRAMs 2500a and 2500b, the four fundamental arithmetic operations, that is, addition/subtraction/multiplication/division operations, vector operations, address operations, or fast fourier transform (FFT) operations may be performed. Also, a function for performing an inference may be performed in the DRAMs 2500a and 2500b. Here, the inference may be performed in a deep learning algorithm using an artificial neural network. The deep learning algorithm may include a training operation of learning a model through various data and an inference operation of recognizing data with the trained model. According to an embodiment, an image taken by a user using the camera 2100 may be signal-processed and stored in the DRAM 2500b, and the accelerator block or accelerator chip 2820 may perform AI data operation for recognizing data by using data stored in the DRAM 2500b and a function used for inference.

The system 2000 may include a plurality of storages or the plurality of flash memories 2600a and 2600b having a larger capacity than the DRAMs 2500a and 2500b. The accelerator block or accelerator chip 2820 may perform a training operation and AI data operation by using the flash memories 2600a and 2600b. According to an embodiment, the flash memories 2600a and 2600b may include a memory controller 2610 and a flash memory device 2620 and may efficiently perform, by using an operator included in the memory controller 2610, the training operation and the inference AI data operation performed by the AP 2800 and/or the accelerator chip 2820. The flash memories 2600a and 2600b may store pictures taken by using the camera 2100 or data transmitted through a data network. For example, the flash memories 2600a and 2600b may store augmented reality/virtual reality, high definition (HD), or ultra high definition (UHD) contents.

In the system 2000, the DRAMs 2500a and 2500b may each be the memory device described in relation to FIGS. 1 to 10. The memory device may include a core peripheral circuit formed on a semiconductor substrate and a cell array structure overlapping the core peripheral circuit structure in the vertical direction on the core peripheral circuit structure. The cell array structure may include a plurality of memory blocks in a memory cell area in which a plurality vertical channel transistor structures and a plurality of capacitor structures respectively connected to the plurality of vertical channel transistor structures are formed. Each of the plurality of memory blocks may include a plurality of word lines extending in a first direction of the memory device, a plurality of back gate lines adjacent to the plurality of word lines, a plurality of bit lines extending in a second direction perpendicular to the first direction, and a shielding bit line arranged between the plurality of bit lines and under the plurality of bit lines. Each of the plurality of memory blocks may include a mesh structure in which the back gate lines are electrically connected to the shielding bit line. The core peripheral circuit structure may include a voltage generator connected to the shielding bit line of each of the plurality of memory blocks. The bonding metal pads in electrical contact with the core peripheral circuit structure and the cell array structure may be electrically connected to the shielding bit line and the back gate lines of the cell array structure and may be electrically connected to the voltage generator of the core peripheral circuit structure. The plurality of driver circuits of the voltage generator may drive the shielding bit line and the plurality of back gate lines of each of the plurality of memory blocks at the same voltage level. As the back gate electrodes and the shielding bit line are commonly controlled at a certain voltage level provided by the voltage generator, the voltage level of the back gate line may remain constant. Accordingly, a change in the threshold voltage of the vertical channel transistor may be prevented, which leads to improved stability of memory cells and improved performance of DRAM.

While the inventive concept has been particularly shown and described with reference to embodiments thereof, it will be understood that various changes in form and details may be made therein without departing from the spirit and scope of the disclosure.

What is claimed is:

1. A memory device comprising:
a plurality of memory blocks each including:
a plurality of word lines extending in a first direction of the memory device,
a plurality of back gate lines, each of the plurality of back gate lines being adjacent to a respective word line of the plurality of word lines,
a plurality of bit lines extending in a second direction perpendicular to the first direction, and
a shielding bit line arranged between adjacent bit lines of the plurality of bit lines and under the plurality of bit lines, wherein each of the plurality of memory blocks includes a mesh structure in which the plurality of back gate lines are electrically connected to the shielding bit line; and
a voltage generator connected to the shielding bit line of each of the plurality of memory blocks,
wherein the voltage generator is configured to drive the shielding bit line and the plurality of back gate lines of each of the plurality of memory blocks at the same voltage level.

2. The memory device of claim 1, wherein the voltage generator is configured to generate an internal power voltage by using a power voltage of the memory device and includes a plurality of driver circuits configured to provide the internal power voltage to the plurality of back gate lines and the shielding bit line.

3. The memory device of claim 2, wherein the internal power voltage has a voltage level identical to a voltage level of the power voltage and is a voltage used for sensing data of memory cells of the plurality of memory blocks.

4. The memory device of claim 1, wherein the voltage generator is configured to generate a bit line precharge voltage by using a power voltage of the memory device and includes a plurality of driver circuits configured to provide the bit line precharge voltage to the plurality of back gate lines and the shielding bit line.

5. The memory device of claim 4, wherein the bit line precharge voltage has a voltage level lower than a voltage level of the power voltage, and
the voltage generator is configured to provide the bit line precharge voltage to the plurality of bit lines before memory cells of the plurality of memory blocks are sensed.

6. The memory device of claim 1, wherein the voltage generator is configured to generate a negative voltage having a negative (−) voltage level lower than a ground voltage level of the memory device and includes a plurality of driver circuits configured to provide the negative voltage to the plurality of back gate lines and the shielding bit line.

7. The memory device of claim 1, wherein the plurality of memory blocks include a first memory block and a second memory block,
the voltage generator is commonly connected to the first memory block and the second memory block, and
the memory device further includes a control logic circuit configured to control the voltage generator.

8. The memory device of claim 7, wherein the control logic circuit is configured to independently control a first voltage level of the shielding bit line and the plurality of back gate lines of the first memory block and a second voltage level of the shielding bit line and the plurality of back gate lines of the second memory block.

9. A memory device comprising:
a core peripheral circuit structure including first bonding metal pads; and
a cell array structure overlapping the core peripheral circuit structure in a vertical direction and including second bonding metal pads respectively in contact with the first bonding metal pads,
wherein the cell array structure includes a memory cell area including a plurality of memory blocks, each of the plurality of memory blocks including:
a plurality of word lines extending in a first direction of the memory device,
a plurality of back gate lines, each of the plurality of back gate lines being adjacent to a respective word line of the plurality of word lines,
a plurality of bit lines extending in a second direction perpendicular to the first direction, and
a shielding bit line arranged between adjacent bit lines of the plurality of bit lines and under the plurality of bit lines, wherein, in each of the plurality of memory blocks, the plurality of back gate lines are electrically connected to the shielding bit line, and the shielding bit line is in contact with the second bonding metal pads,
the core peripheral circuit structure includes a voltage generator electrically connected to the first bonding metal pads, and
the voltage generator is configured to drive the shielding bit line and the plurality of back gate lines of each of the plurality of memory blocks at the same voltage level.

10. The memory device of claim 9, wherein the voltage generator includes:
a voltage generation circuit configured to generate an internal power voltage, a bit line precharge voltage, and a negative voltage by using a power voltage of the memory device;
a first driver configured to provide, to an internal power voltage line, the internal power voltage transmitted through a first switch connected to the voltage generation circuit;
a second driver configured to provide, to a bit line precharge voltage line, the bit line precharge voltage transmitted through a second switch connected to the voltage generation circuit; and
a third driver configured to provide, to a negative voltage line, the negative voltage transmitted through a third switch connected to the voltage generation circuit,
the voltage generator is configured to provide a ground voltage of the memory device to a ground voltage line, and
each of the internal power voltage line, the bit line precharge line, the negative voltage line, and the ground voltage line is electrically connected to the first bonding metal pads.

11. The memory device of claim 10, wherein the first driver includes a plurality of first driver circuits configured to drive the internal power voltage line, the second driver includes a plurality of second driver circuits configured to drive the bit line precharge line, and the third driver includes a plurality of third driver circuits configured to drive the negative voltage line.

12. The memory device of claim 10, wherein the internal power voltage has a voltage level identical to a voltage level of the power voltage and is a voltage used for sensing data of memory cells of the plurality of memory blocks.

13. The memory device of claim 10, wherein the bit line precharge voltage has a voltage level lower than a voltage level of the power voltage, and
the second driver is configured to provide the bit line precharge voltage to the plurality of bit lines before memory cells of the plurality of memory blocks are sensed.

14. The memory device of claim 10, wherein the negative voltage has a negative (−) voltage level lower than a voltage level of the ground voltage, and
the third driver is configured to provide the negative voltage as a bulk bias voltage or a back bias voltage applied to a well area in which NMOS transistors of the first driver, the second driver, and the third driver are formed.

15. The memory device of claim 9, wherein the plurality of memory blocks include a first memory block and a second memory block,
the voltage generator is commonly connected to the first memory block and the second memory block, and
the memory device further includes a control logic circuit configured to control the voltage generator.

16. The memory device of claim 15, wherein the control logic circuit is configured to independently control a first voltage level of the shielding bit line and the plurality of back gate lines of the first memory block and a second voltage level of the shielding bit line and the plurality of back gate lines of the second memory block.

17. A memory device comprising:
a plurality of memory blocks each including:
a plurality of word lines extending in a first direction of the memory device,
a plurality of back gate lines, each of the plurality of back gate lines being adjacent to a respective word line of the plurality of word lines,
a plurality of bit lines extending in a second direction perpendicular to the first direction, and
a shielding bit line arranged between adjacent bit lines of the plurality of bit lines and under the plurality of bit lines; and
a voltage generator configured to drive the shielding bit line and the plurality of back gate lines of each of the plurality of memory blocks at the same voltage level,
wherein the voltage generator includes:
a voltage generation circuit configured to generate, by using a power voltage of the memory device, an internal power voltage having the same voltage level as the power voltage, a bit line precharge voltage having a lower voltage level than the power voltage, and a negative voltage having a lower voltage level than a ground voltage of the memory device;
a first driver configured to provide, to an internal power voltage line, the internal power voltage transmitted through a first switch connected to the voltage generation circuit;
a second driver configured to provide, to a bit line precharge voltage line, the bit line precharge voltage transmitted through a second switch connected to the voltage generation circuit; and
a third driver configured to provide, to the back gate lines and the shielding bit line, the negative voltage transmitted through a third switch connected to the voltage generation circuit,
the voltage generator is configured to provide the ground voltage of the memory device to a ground voltage line, and
each of the internal power voltage line, the bit line precharge voltage line, the negative voltage line, and the ground voltage line is electrically connected to the shielding bit line and the back gate lines of each of the plurality of memory blocks.

18. The memory device of claim 17, wherein the first driver includes a plurality of first driver circuits configured to drive the internal power voltage line, the second driver includes a plurality of second driver circuits configured to drive the bit line precharge line, and the third driver includes a plurality of third driver circuits configured to drive the negative voltage line.

19. The memory device of claim 17, wherein the plurality of memory blocks include a first memory block and a second memory block,
the voltage generator is commonly connected to the first memory block and the second memory block, and
the memory device further includes a control logic circuit configured to control the voltage generator.

20. The memory device of claim 19, wherein the control logic circuit is configured to control a first voltage level of the shielding bit line and the back gate lines of the first memory block and a second voltage level of the shielding bit line and the back gate lines of the second memory block.
